(19) United States
(12) Patent Application Publication
(10) Pub. No.: US 2003/0030857 A1
(43) Pub. Date: Feb. 13, 2003

(54) Image processing method and image output apparatus

(75) Inventor: Yuki Ito, Kawasaki (JP)

Correspondence Address: ARMSTRONG,WESTERMAN & HATTORI, LLP, 1725 K STREET, NW., SUITE 1000, WASHINGTON, DC, 20006, US

(73) Assignee: Fujitsu Limited, Kawasaki (JP)

(21) Appl. No.: 10/105,260

(22) Filed: Mar. 26, 2002

(30) Foreign Application Priority Data
Aug. 8, 2001 (JP) 2001-241200

(51) Int. Cl. B41J 1/00; G06F 15/00; G03F 3/08

(52) U.S. Cl. 358/521; 358/1.9

(57) ABSTRACT

An image processing method that processes input image data represented by a plurality of gradation levels from a minimum to a maximum includes the steps as follows: a first binarization step that extracts a matrix of m pixels×n pixels (m, n: integer) from the input image data, and performs a binarization process on each pixel in the matrix so that each of the pixels having the minimum gradation level is binarized into “0”, and each of the pixels having a level other than the minimum gradation level is binarized into “1”; a blank emphasis step that performs a blank emphasis process on each pixel in a matrix binarized in the first binarization step; and a correction step that performs a color correction process on each of the pixels in the matrix subjected to the blank emphasis process in the blank emphasis step.

### BACKGROUND OF THE INVENTION

1. Field of the Invention

The present invention relates to an image processing method and an image output apparatus, and more particularly, to an image processing method which emphasizes a blank part of an image by an image output apparatus such as a printer or a display and an image output apparatus employing such an image processing method.

In this specification, the blank part refers to a part where pixel data are not printed when printing an image by the printer, that is, a part where white remains after printing when a recording medium is a sheet of white paper. Additionally, blank part means a part where the pixel data are not displayed when displaying the pixel data on a display, that is, a part where white color remains when a color of a background of the display is white. Thus, it is not always necessary for the blank part to be white. The color of the blank part depends on the color of the recording medium or on the background of the display.

2. Description of the Related Art

Image data generated by a computer or the like are output from the image output apparatus such as the printer or the display. Especially, when the image data are characters or line drawings, a smoothing process, which is a process for improving image quality, is performed so as to make notches of pixels (dots), namely, the jaggy part, inconspicuous. The smoothing process itself is well known and various smoothing methods are proposed with regard to binary and multi-valued (multi-level) image data.

Additionally, as the process for improving the image quality, there is a blank emphasis process which emphasizes the blank parts. In a case of binary image data, outline characters on a colored background often become unclear since the characters are outlined by a black color, for example, causing the surrounding black dots to come inside the characters due to bleeding or the like. Blank emphasis makes an area of blank part larger than an actual area to some degree so as to emphasize white dots (blank part) with respect to the surrounding black dots. Such a blank emphasis process itself is well known.

In a case of multi-valued image data, as for the blank emphasis process, a method is proposed in which the above-mentioned blank emphasis is performed only when the pixels surrounding the blank part are at the maximum gradation level, that is, a level at which the pixels are the blackest.

However, in the case of the multi-valued image data, there is a problem in that the blank part is unclear when a gradation level of the pixels surrounding the blank part is not the maximum gradation level, since the blank emphasis is not performed.

### SUMMARY OF THE INVENTION

Accordingly, it is a general object of the present invention to provide a novel and useful image processing method and image output apparatus, in which the problems described above are eliminated.

A more specific object of the present invention is to provide an image processing method and an image output apparatus that can perform blank emphasis irrespective of the gradation level of the pixels surrounding the blank part and can output the blank part clearly.

The objects mentioned above can be achieved, according to one aspect of the present invention, by an image processing method that processes input image data represented by a plurality of gradation levels from a minimum to a maximum, comprising: a first binarization step that extracts a matrix of m pixels×n pixels (m, n: integer) from the input image data, and performs a binarization process on each pixel in the matrix so that each of the pixels having the minimum gradation level is binarized into “0”, and each of the pixels having a level other than the minimum gradation level is binarized into “1”; a blank emphasis step that performs a blank emphasis process on each pixel in a matrix binarized in the first binarization step; and a correction step that performs a color correction process on each of the pixels in the matrix subjected to the blank emphasis process in the blank emphasis step.

The correction step may be such that a correction process is performed to each of the pixels in the matrix subjected to the blank emphasis, the correction process being represented by: (data value after blank emphasis)×{(gradation level of input image data)/(the maximum gradation level)}.

The objects mentioned above are also achieved, according to another aspect of the present invention, by an image output apparatus that processes and outputs input image data represented by a plurality of gradation levels from a minimum to a maximum, comprising: a binarization part that extracts a matrix of m pixels×n pixels (m, n: integer) from the input image data, and performs a binarization process on each pixel in the matrix so that each of the pixels having the minimum gradation level is binarized into “0”, and each of the pixels having a level other than the minimum gradation level is binarized into “1”; a blank emphasis part that performs a blank emphasis process on each pixel in a matrix binarized in the first binarization part; and a correction part that performs a color correction process on each pixel in the matrix subjected to the blank emphasis process in the blank emphasis part.

The image output apparatus can be a structure further comprising: a second binarization part that extracts a matrix of m pixels×n pixels from the input image data, and performs a binarization process on each pixel in the matrix so that each of the pixels having the maximum gradation level is binarized into “1”, and each of the pixels having a level other than the maximum gradation level is binarized into “0”; a smoothing part that performs a smoothing process on each pixel in a matrix binarized in the second binarization part; and an output part that selects and outputs, according to a priority, either data obtained by the correction part or data obtained by the smoothing part. In this case, it is possible to select either the blank emphasis or the smoothing according to a priority.

Additionally, the image output apparatus can be a structure further comprising: a second binarization part that extracts a matrix of m pixels ×n pixels from the input image data, and performs a binarization process on each pixel in the matrix so that each of the pixels having the maximum gradation level is binarized into “1”, and each of the pixels having a level other than the maximum gradation level is binarized into “0”; a smoothing part that performs a smoothing process on each pixel in the matrix binarized in the second binarization part; and a selecting means that selects, according to a priority, whether to make the first binarization part, the blank emphasis part and the correction part valid, or to make only the second binarization part and the smoothing part valid. In this case, it is possible to select either the blank emphasis or the smoothing according to a priority.

Therefore, according to the present invention, it is possible to emphasize a blank part irrespective of gradation levels of pixels surrounding the blank part. Thus, it is possible to realize an image processing method and an image output apparatus that can output the blank part clearly.

Other objects, features and advantages of the present invention will become more apparent from the following detailed description when read in conjunction with the following drawings.

### BRIEF DESCRIPTION OF THE DRAWINGS

FIG. 1 is a block diagram showing an embodiment of an image output apparatus according to the present invention;

FIGS. 2A, 2B, 2C, 2D and 2E are schematic diagrams for explaining a process of an image processing part in a case where pixels surrounding a blank part are at the maximum gradation level;

FIGS. 3A, 3B, 3C, 3D and 3E are timing diagrams for explaining relationships among light-emitting time corresponding to a pixel and light-emitting times of the pixels on which a smoothing process is performed;

FIGS. 4A, 4B, 4C, 4D, 4E and 4F are schematic diagrams for explaining a process of an image processing part in a case where pixels surrounding a blank part are halftone;

FIG. 5 is a flow chart for explaining an operation of a controller;

FIG. 6 is another flow chart for explaining the operation of the controller;

FIG. 7 is a schematic diagram for explaining a setting method of priority and the like;

FIGS. 8A and 8B are schematic diagrams for explaining a blank emphasis process;

FIGS. 9A, 9B, 9C, 9D, 9E and 9F are schematic diagrams for explaining input data on which a smoothing process and a blank emphasis process can be performed at the same time; and

FIGS. 10A and 10B are schematic diagrams for explaining output patterns corresponding the input data on which the smoothing process and the blank emphasis process can be performed at the same time.

### DETAILED DESCRIPTION OF THE PREFERRED EMBODIMENTS

A description will be given of various embodiments of an image processing method and an image output apparatus according to the present invention, by referring to the drawings.

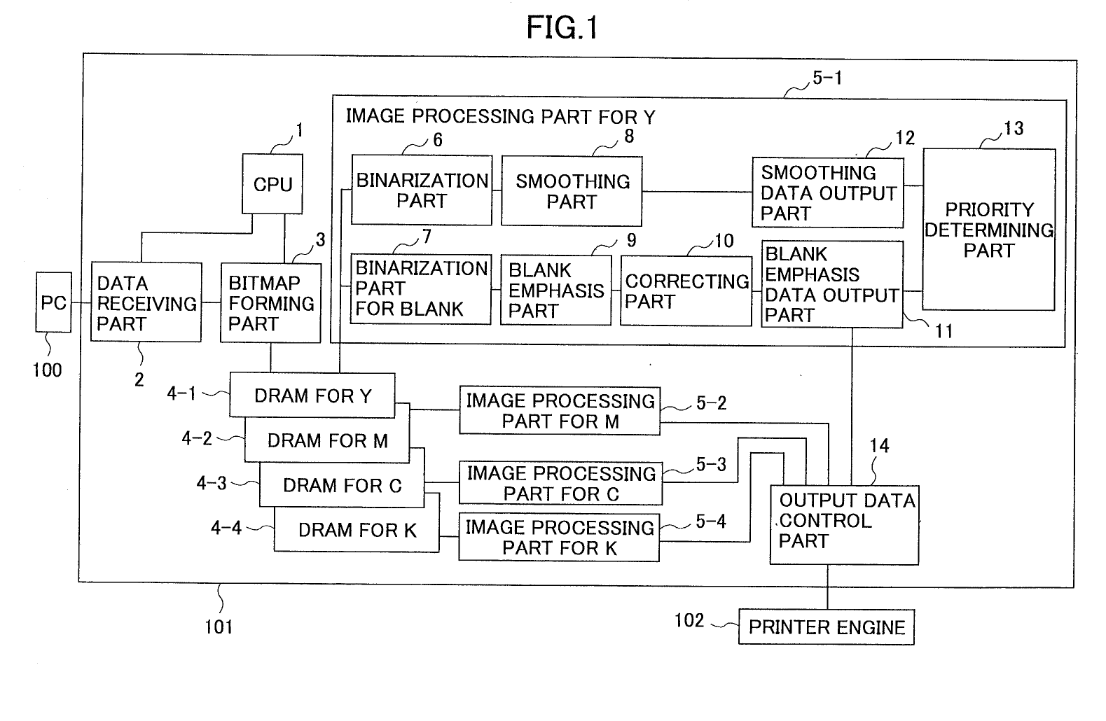

FIG. 1 is a block diagram showing an embodiment of the image output apparatus according to the present invention. The image output apparatus of this embodiment employs an embodiment of the image processing method according to the present invention.

The image output apparatus shown in FIG. 1 is generally provided with a controller 101 and a printer engine 102. A personal computer (PC) 100 having a known structure is connected with the controller 101 directly or through a network. In this embodiment, it is assumed for the sake of convenience that the printer engine 102 is structured using a printer engine such as an electrophotographic printer having a known structure. It is also assumed that the personal computer 100 functions as a host apparatus with respect to a color printer.

When the present invention is applied to a multi-valued color display, the printer engine 102 is structured using a display engine having a known structure such as CRT, LCD, PDP or the like. The printer engine is provided on a personal computer 100 side.

The controller 101 includes a CPU 1, a data receiving part 2, a bitmap forming part 3, DRAMs 4-1, 4-2, 4-3 and 4-4 for yellow (Y), magenta (M), cyan (C) and black (K), which are primary colors in printing, respectively, image processing parts 5-1, 5-2, 5-3 and 5-4 for Y, M, C and K, respectively, and an output data control part 14. Each of the image processing parts 5-1, 5-2, 5-3 and 5-4 for Y, M, C and K, respectively, has the same structure. Thus, in FIG. 1, only a structure of the image processing part 5-1 for Y is shown.

Each of the image processing parts 5-1, 5-2, 5-3 and 5-4 for Y, M, C and K, respectively, includes a binarization part 6, a binarization part for blank 7, a smoothing part 8, a blank emphasis part 9, a correcting part 10, a blank emphasis data output part 11, a smoothing data output part 12 and a priority determining part 13. This embodiment is characterized by the structure of the controller 101, and especially by the structures of the image processing parts 5-1, 5-2, 5-3 and 5-4 for Y, M, C and K, respectively.

The CPU 1 in the controller 101 controls a total operation of the controller 101. When the PC 100 issues a printing order, and the multi-valued color image data (printing data) is sent to the controller 101, the data receiving part 2 receives the image data. Then, the bitmap forming part 3 generates bitmap data under the control of the CPU 1. In this embodiment, the printer engine 102 prints the color image by using the four colors Y, M, C and K. Accordingly, the bitmap forming part 3 divides the image data into four colors by the bitmap. The image data has a gradation level for each dot. For example, in a case of 16 gradations, each single dot is expressed by pixel data having a four-bit structure, which can express the gradation levels of 0 through 15. The bitmap data for each of Y, M, C and K are stored in the corresponding DRAM 4-1, 4-2, 4-3 and 4-4, respectively. Each image processing part 5-i (i=1, 2, 3, 4) reads the bitmap data of the corresponding color from the corresponding DRAM 4-i. Then, the extracted data is input to the binarization part 6 and the binarization part 7, which are in the image processing part 5-i.

The binarization part 6 has the same structure as a binarization part used in a conventional smoothing process. The binarization part 6 binarizes the pixel data into “1” and “0” when the pixel data is at the maximum gradation level and at a level other than the maximum gradation level, respectively. Further, it may be possible that the binarization part 6 has a structure such that the pixel data is binarized into “0” and “1” when the pixel data is at a gradation level of and above a threshold value and below the threshold value, respectively. The smoothing part 8 performs the smoothing process on the binarized pixel data based on a predetermined smoothing algorithm. Then, the binarized pixel data to which the smoothing process is performed are provided to the smoothing data output part 12. The smoothing data output part 12 provides smoothened binarized data to the priority determining part 13, a description of which will be given later.

On the other hand, the binarization part 7 binarizes the pixel data into “1”s and “0”s when the pixel data are at other than the minimum gradation level or the maximum gradation level, and at the minimum gradation level, respectively. The blank emphasis part 9 performs the blank emphasis process on the binarized data based on an algorithm for the blank part. The binarized pixel data on which the blank emphasis process is performed are provided to the correcting part 10. The correcting part 10 performs a process of correcting the result of the blank emphasis process when the data input is halftone. The correcting part 10 provides the binarized data in which the blank part is emphasized and corrected to the blank emphasis data output part 11. The binarized data which is output by the blank emphasis data output part 11 is provided to the priority determining part 13.

The priority determining part 13 selects and outputs either of the two sets of binarized data by prioritizing when both sets of binarized data are provided as described later. That is, the binarized data from the smoothing data output part 12 (result of the smoothing) and the binarized data from the blank emphasis data output part 11 (result of the blank emphasis). The output data control part 14 outputs the image data to be printed to the printer engine 102 in synchronization with the printer engine 102.

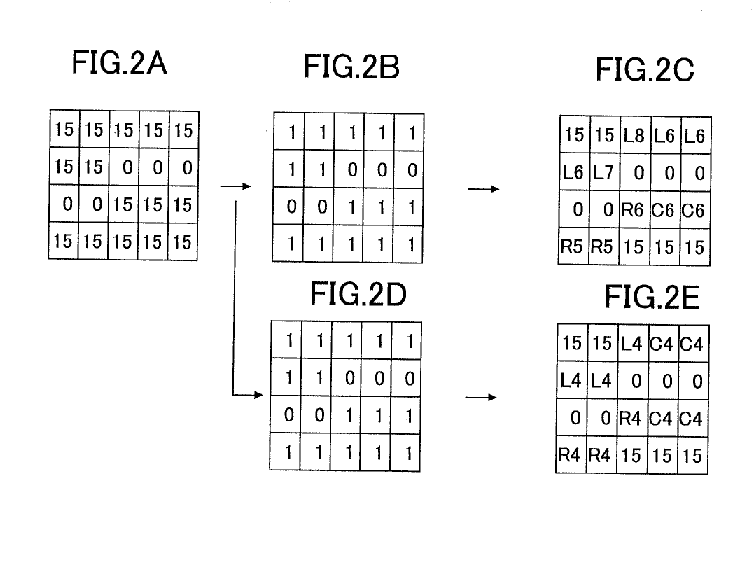

FIGS. 2A, 2B, 2C, 2D and 2E are schematic diagrams for explaining a process of the image processing part 5-i in a case where the pixels surrounding the blank part (or outline characters on a colored background) are at the maximum gradation level.

FIG. 2A shows a matrix of input data read by the corresponding DRAM 4-i. For convenience of explanation, the input data are indicated by the matrix of 4 pixels×5 pixels. The maximum gradation level is “15”, and the minimum gradation level is “0”. For example, in a case of the cyan, the cyan is 100 percent when the pixel data are at the maximum gradation level. On the other hand, the cyan becomes 0 percent, that is, a color of the recording medium (white) when the pixel data are at the minimum gradation level. In this embodiment, a horizontal bar at the minimum gradation level (blank part) surrounded by the pixels at the maximum gradation level exists in the matrix of 4×5 pixels.

FIG. 2B is a matrix of a result of a binarization process for the smoothing performed by the binarization part 6 with regard to the input data. In the binarization process for smoothing, the image quality may be rather deteriorated when the smoothing process is performed on the pixels of halftone. For this reason, the pixels at the maximum gradation level “15” are binarized into “1”, and the pixels at a level other than the maximum gradation level “15” are binarized into “0”.

FIG. 2C is a matrix of a result of the smoothing process by the smoothing part 8 with respect to the binarized matrix of the FIG. 2B. In FIG. 2C, R means printing the pixel (dot) on a right side, C means printing in the center and L means printing on a left side. Accordingly, “R6”, for example, means printing on the right side of the pixel with a 1/16 size of the pixel. “L6” means printing on the left side of the pixel with a 1/16 size of the pixel, and “C6” means printing in the center of the pixel with a 1/16 size of the pixel. The same expression will be used in drawings referred to later.

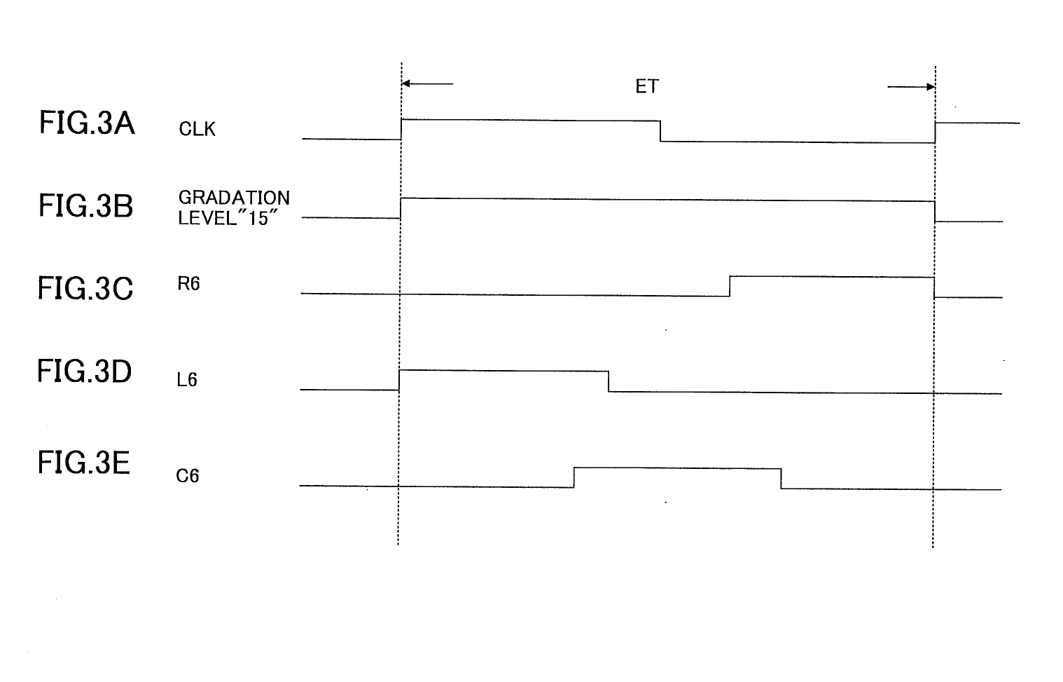

FIGS. 3A, 3B, 3C, 3D and 3E are schematic diagrams for explaining relationships among a light-emitting time ET corresponding to a pixel (dot) of a light source such as a laser diode used in the printer engine 102 of 600 dpi, and light-emitting times corresponding to the pixels on which the smoothing process is performed. FIG. 3A shows a video clock CLK which forms a basis of controlling the light-emitting time of the light source. FIG. 3B shows the light-emitting time to the pixel “15” at the maximum gradation level. FIGS. 3C, 3D and 3E show the light-emitting times to the pixels “R6”, “L6” and “C6”, respectively.

The above-mentioned binarization process of the binarization part 6 and the smoothing process of the smoothing part 8 are well known, and it is possible to realize both processes by respective known circuit structures.

FIG. 2D is a matrix of a result of the binarization process for blank performed by the binarization part 7. FIG. 2E is a matrix of a result of the blank emphasis process performed by the blank emphasis part 9 on the binarized matrix of the FIG. 2D. The blank emphasis process emphasizes the blank part by thinning the surrounding area of the pixel having the binary level of “0”. In this case, the correcting part 10 does not perform a process on the input data input to the image processing part 5-i since the pixels surrounding the blank part are at the maximum gradation level “15”. The data from the blank emphasis part 9 passes through the correcting part 10 to the blank emphasis data output part 11.

The binarization process of the binarization part 7 and the blank emphasis process of the blank emphasis part 9 on the input data in which the pixels surrounding the blank part are on the maximum gradation level “15” are known. It is possible to realize both processes by respective known circuit structures.

The smoothing data output part 12 and the blank emphasis data output part 11 provide the data from the smoothing part 8 and the data from the compensation part 10 to the priority determining part 13, respectively, with matching timing. The priority determining part 13 selects and outputs the data to the printer engine 102 through the output data control part 14. The priority determining part 13 selects the data based on a setting provided concurrently with the printing order from the PC 100, for example. The data are selected whether the setting prioritizes the smoothing process or the blank emphasis process. The data on which the process equivalent to the setting is performed are selected. Thus, basically, the process of the image processing part 5-i to the input data in which the pixels surrounding the blank part are at the maximum gradation level “15” is the same as a well known process. Further, not the PC 100 but the printer may determine the setting whether to prioritize the smoothing process or the blank emphasis process.

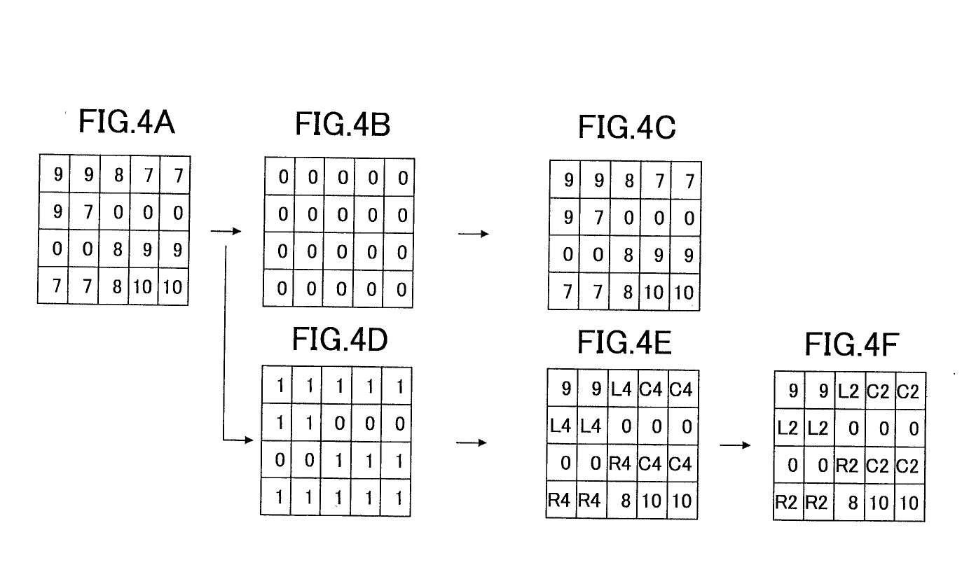

FIGS. 4A, 4B, 4C, 4D, 4E and 4F are schematic diagrams for explaining a process of the image processing part 5-i in a case where the pixels surrounding the blank part (or outline characters in a colored background) are at levels other than the maximum gradation level and the minimum gradation level, that is, halftone.

FIG. 4A is a matrix of input data read from the corresponding DRAM 4-i. For convenience of explanation, the input data are represented by a matrix of 4 pixels×5 pixels. The maximum gradation level thereof is “15”, and the minimum gradation level thereof is “0”. In this embodiment, a horizontal bar exists in the matrix of 4 pixels×5 pixels, the horizontal bar being at the minimum gradation level (blank) surrounded by the halftone pixels.

FIG. 4B is a matrix of a result of performing the binarization process for smoothing on the input data by the binarization part 6. In this case, all the pixels are binarized into “0” by the binarization process for the smoothing since the pixels at the maximum gradation level “15” do not exist. Thus, the smoothing process can not be performed in this case. As shown in FIG. 4C, the input data showed in FIG. 4A are obtained as a matrix as a result of the smoothing process performed by the smoothing part 8.

FIG. 4D is a matrix of a result of performing the binarization process for blank part by the binarization part 7. The binarization part 7 binarizes all the pixels at levels other than the minimum gradation level into “1”. FIG. 4E is a matrix of a result of performing the blank emphasis process by the blank emphasis part 9 on the binarized matrix shown in FIG. 4D. As mentioned above, the blank emphasis process emphasizes the blank part by thinning the pixels surrounding the binarization level “0”. In this case, the correction part 10 performs the correction process since the input data which is input to the image processing part 5-i includes the pixels surrounding the blank part and being at levels other than the maximum gradation level “15”, that is, halftone.

To be more precise, the correction part 10 performs the color correction on each pixel for adjusting tone of a part surrounding the blank part by dividing the gradation level of the original input data by the maximum gradation level “15”, and multiplying an answer thereof by a value after the blank emphasis. Take “L4”, which is in the middle row of the top line of the matrix shown in FIG. 4E, for example. The color correction is performed by a formula: (4/15)×8≈2.1. The answer (2.1) is rounded to be an integer (2), thus “L2” is obtained. In the same way, take “C4”, which is in the right most row of the top line of the matrix showed in FIG. 4E, for example. The color correction is performed by a formula: (4/15)×7≈1.8. The answer (1.8) is rounded up to be an integer (2), thus “C2” is obtained. FIG. 4F shows a result of the color correction performed by the correction part 10. The data output by the correction part 10 are provided to the blank emphasis data output part 11.

The blank emphasis process itself of the blank emphasis part 9 for the input data in which the pixels surrounding the blank part are halftone is the same as the process in a case where the pixels surrounding the blank part are at the maximum gradation level “15”. It is possible to realize the blank emphasis process by a well-known circuit structure.

The smoothing data output part 12 and the blank emphasis data output part 11 provide the data from the smoothing part 8 and the data from the compensation part 10 to the priority determining part 13, respectively, with matching timing. The priority determining part 13 selects and outputs the data to the printer engine 102 through the output data control part 14. The priority determining part 13 selects the data based on a predetermined setting. The data are selected whether the setting prioritizes the smoothing process or the blank emphasis process. The data to which the process equivalent to the setting is performed are selected.

The output data control part 14 provides the data for Y, M, C and K from the image processing parts 5-1, 5-2, 5-3 and 5-4 for the Y, M, K and C, respectively, to the corresponding image forming parts for Y, M, C and K of the printer engine 102, respectively.

Accordingly, in this embodiment, the binarization process for the blank part is performed in addition to the binarization process for the smoothing, which is the same as a conventional process. The binarization process for the smoothing binarizes the pixels surrounding the blank part into “1” only when the pixels are at the maximum gradation level “15”. On the other hand, the binarization process for the blank part binarizes the surrounding pixels into “1” when the pixels are halftone.

It is possible to use a conventional algorithm for the blank emphasis process which is performed after the binarization process for the blank part. Then, the color correction is performed on a result of the blank emphasis in consideration of the original gradation level of the pixels of the input data. Therefore, according to a predetermined setting which determines whether to prioritize the smoothing process or blank emphasis process, it is possible to print data to which the predetermined setting is applied.

As a result, it is possible to emphasize the blank part appropriately even when the blank part such as outline characters exists in a halftone part. For example, when the outline characters exist in a green background, the characters, which are easily seen, can be printed by emphasizing the outline characters, resulting in improvement of an image of a color printer.

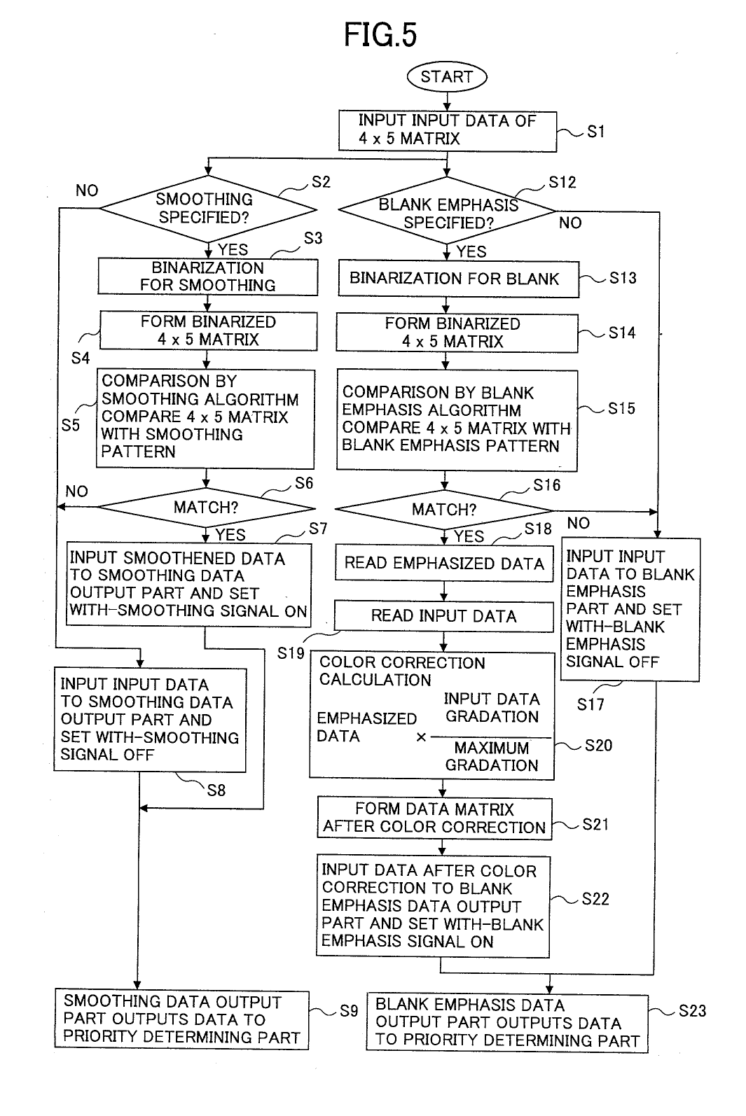

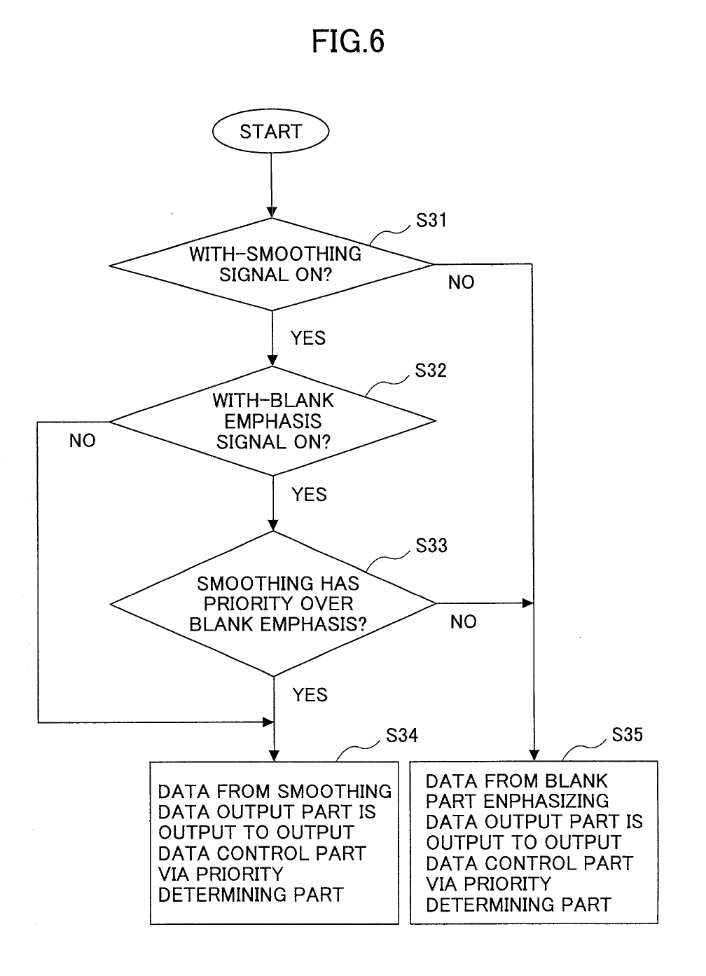

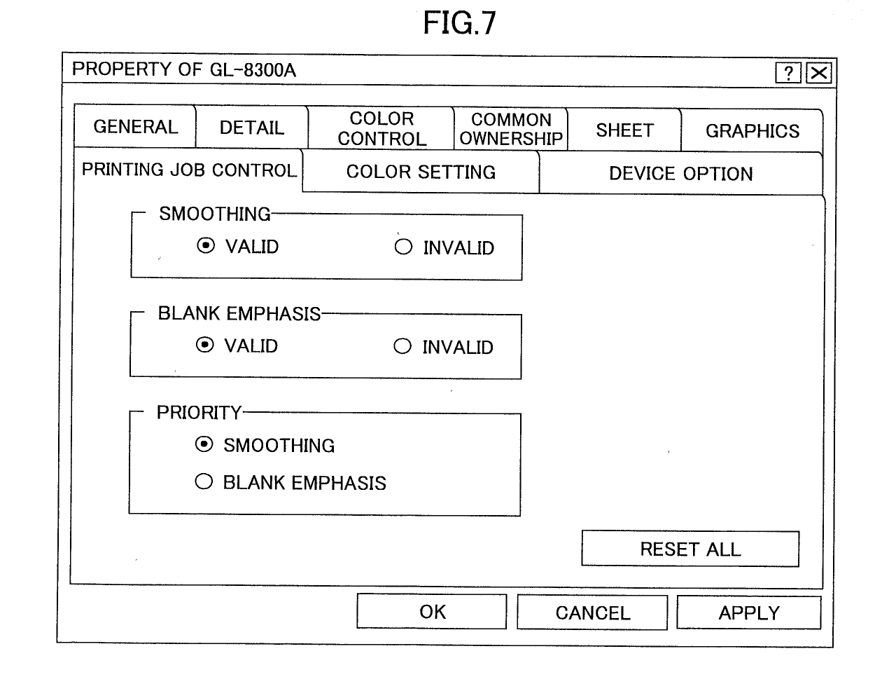

Next, a description will be given of an operation of the controller 101, referring to FIGS. 5 through 7. FIGS. 5 and 6 are flow charts for explaining the operation of the controller 101. For convenience of explanation, FIGS. 5 and 6 show processes of the controller 101 relating to the image processing part 5-i. Needless to say, the same processes are performed to the image processing parts 5-1, 5-2, 5-3 and 5-4 for Y, M, C and K, respectively. In addition, FIG. 7 is a schematic diagram for explaining a setting method of the priority and the like.

FIG. 5 shows the operation relating to the binarization part 6, the binarization part 7, the smoothing part 8, the blank emphasis part 9, the correction part 10, the blank emphasis data output part 11 and the smoothing data output part 12. In FIG. 5, step S1 inputs input data of a matrix (window) of 4 pixels×5 pixels from image data received from the data receiving part 2. After step S1, steps S2 through S9 and steps S12 through S23 are performed in parallel.

Step S2 determines whether or not the smoothing is specified. When performing a printing process setting by a printer driver of the PC 100, a window as shown in FIG. 7 is displayed on a display of the PC 100. In the window shown in FIG. 7, by operating the mouse or a keyboard of the PC 100, a user sets up the setting: whether to make the smoothing valid or invalid, whether to make the blank emphasis valid or invalid, whether to prioritize the smoothing or the blank emphasis, and the like. Further, the same setting may be set up by an operation panel of the printer.

When the smoothing is set to be valid, a decision result in step S2 is YES, and step S3 performs the binarization process for the smoothing. Thus, all the pixels at levels other than the maximum gradation level “15” are binarized into “0”, and the pixels at the maximum gradation level “15” are binarized into “1”. In step S4, the binarization part 6 forms a matrix (window) of 4 pixels×5 pixels on which the binarization process for the smoothing is performed. In step S5, the smoothing part 8 compares the matrix of 4 pixels×5 pixels on which the binarization process for the smoothing is performed and the smoothing pattern of the matrix (window) of 4 pixels×5 pixels. In step S6, the smoothing part 8 determines whether or not a matching smoothing pattern exists. When a decision result of the smoothing part 8 is YES, the smoothened data are output to the smoothing data output part 12 from the smoothing part 8. At the same time, a with-smoothing signal (flag) is set ON, and the process proceeds to step S9.

On the other hand, when the decision result in step S2 is NO, or the decision result in the step S6 is NO, the processes are not performed by the binarization part 6 and the smoothing part 8 in step S8. Thus, the input data are output to the smoothing data output part 12 as is. At the same time, the with-smoothing signal (flag) is set OFF, and the process proceeds to step S9. In step S9, the smoothing data output part 12 outputs the smoothened data or the input data to the priority determining part 13.

On the other hand, step S12 determines whether or not the blank emphasis is specified. A decision result in step S12 is YES when the blank emphasis is set to be valid in the window showed in FIG. 7. In this case, in step S13, the binarization part 7 performs the binarization process for the blank part. Thus, the pixels at the minimum gradation level “0”. are binarized into “0”, and the all the pixels at gradation levels other than the minimum gradation level “0”, that is, the halftone pixels are binarized into “1”. In step S14, the binarization part 7 forms a matrix (window) of 4 pixels×5 pixels to which the binarization process is performed. In step S15, the blank emphasis part 9 compares the matrix (window) of 4 pixels×5 pixels to which the binarization process for the blank part is performed and the matrix (window) of 4 pixels×5 pixels of the blank emphasis pattern by a well-known blank emphasis algorithm. In step S16, the blank emphasis part 9 determines whether or not a matching blank emphasis pattern exists.

The well-known smoothing algorithm used in step S5 and the well-known blank emphasis algorithm used in step S15 have been already employed, for example, in a FEIT PHOTO LSI (a custom LSI manufactured by FUJITSU LIMITED), which is carried in a printer GL760S manufactured by FUJITSU LIMITED.

The process proceeds to step S17 when the decision result in step S12 is NO or when the decision result in step S16 is NO. In step S17, the input data passes through the binarization part 7, the blank emphasis part 9 and the correction part 10 without any process being performed. Thus, the input data are output to the blank emphasis data output part 11 as is. At the same time, a with-blank emphasis signal (flag) is set OFF, and the process proceeds to step S23.

On the other hand, when the decision result in step S16 is YES, the correction part 10 reads the data after the blank emphasis from the blank emphasis part 9. In step S19, the input data are read. Further, in step S20, the correction part 10 performs the color correction process by a formula: (data value after blank emphasis)×{(gradation level of input data)/(maximum gradation level)}. In step S21, the correction part 10 forms a matrix of 4 pixels×5 pixels on which the correction after the blank emphasis (color correction process) is performed. In step S22, the data on which the color correction is performed are output from the correction part to the blank emphasis data output part 11. At the same time, the with-blank emphasis signal (flag) is set ON, and the process proceeds to S23. In step S23, the data on which the blank emphasis process is performed are output from the blank emphasis data output part 11 to the priority determining part 13.

FIG. 6 shows an operation of the image processing part 5-i relating to the priority determining part 13. In FIG. 6, step S31 determines whether or not the with-smoothing signal (flag) is set ON. When a decision result in step S31 is YES, step 32 determines whether or not the with-blank emphasis signal (flag) is set ON. When a decision result in step S32 is YES, step S33 determines whether or not the priority is given to the smoothing over the blank emphasis. FIG. 7 shows a case where the smoothing is valid, the blank emphasis is valid, and the smoothing is prioritized. When the decision result in step S33 is YES or the decision result in step S32 is NO, the smoothing is prioritized. Thus, in step S34, the data input to the priority determining part 13 from the smoothing data output part 12 are output to the output data control part 14. On the other hand, when the decision result in step S33 is NO or the decision result in step S31 is NO, the blank emphasis is prioritized. Thus, in step S25, the data output from the blank emphasis data output part 11 are output from the priority determining part 13 to the output data control part 14.

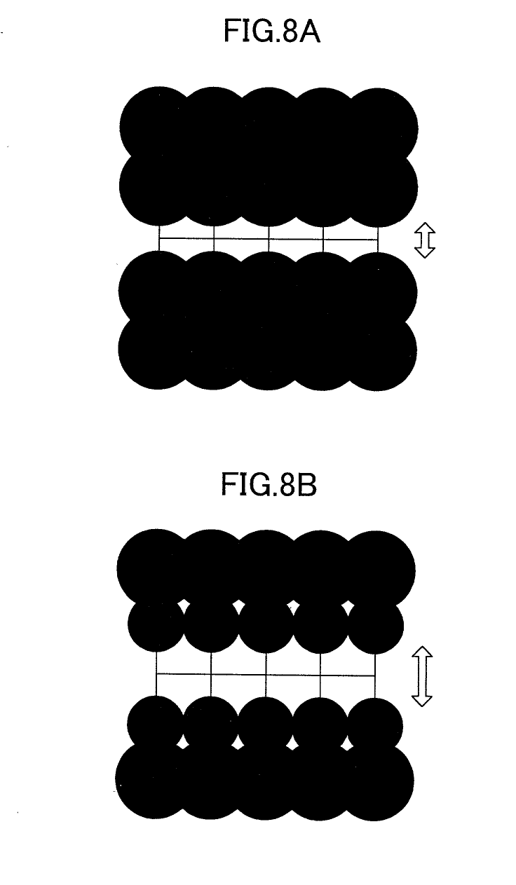

Additionally, as a result of the blank emphasis, a pattern showed in FIG. 8A is emphasized as a pattern showed in FIG. 8B, for example. Thus, the blank pattern is emphasized.

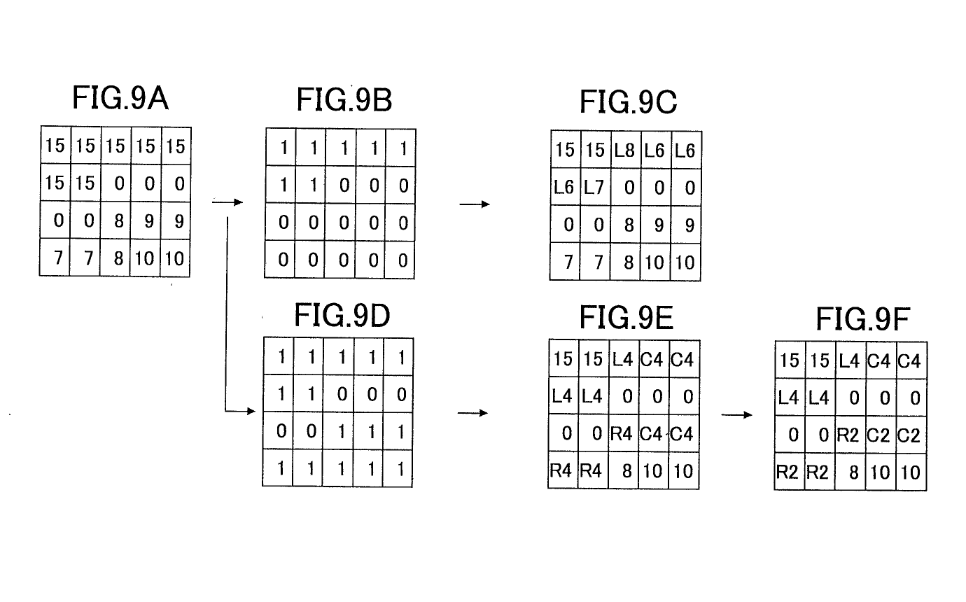

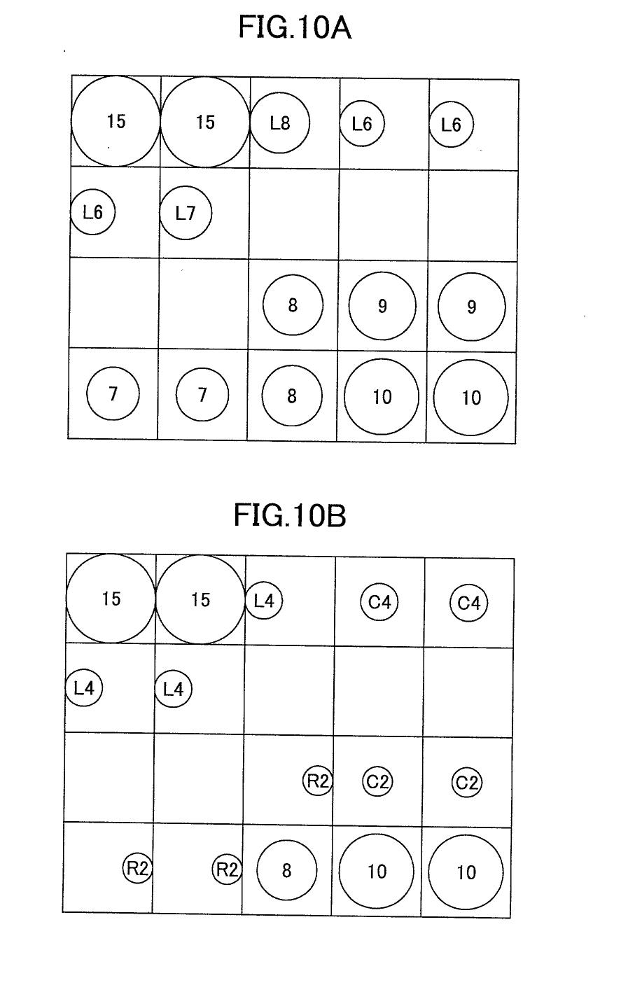

In a case of the input data showed in FIG. 4A, it is impossible to perform the smoothing process since pixels at the maximum gradation level “15” are not included. Therefore, an explanation will be given of input data to which both the smoothing process and the blank emphasis process can be performed and of a corresponding output pattern, referring to FIGS. 9A, 9B, 9C, 9D, 9E, 9F, 10A and 10B. FIGS. 9A through 9F are schematic diagrams for explaining the input data on which both the smoothing process and the blank emphasis process can be performed. FIGS. 10A and 10B are schematic diagrams for explaining the output pattern corresponding to the input data on which both the smoothing process and the blank emphasis process can be performed.

FIG. 9A is a matrix of input data read from the corresponding DRAM 4-i. For convenience of explanation, the input data are shown by a matrix of 4 pixels×5 pixels. The maximum gradation level thereof is “15”, and the minimum gradation level thereof is “0”. In this example, a horizontal bar of the minimum gradation level (blank) exists in the matrix of 4 pixels×5 pixels. The horizontal bar is surrounded by the pixels at the maximum gradation level “15” and the halftone pixels.

FIG. 9B is a matrix of a result of the binarization process for the smoothing by the binarization part 6. FIG. 9C is a matrix of a result of the smoothing process by the smoothing part 8.

FIG. 9D is a matrix of a result of the binarization process for the blank part by the binarization part 7. FIG. 9E is a matrix of a result of the blank emphasis process by the blank emphasis part 9, with respect to the binarized matrix of FIG. 9D. FIG. 9F shows a result of the color correction performed by the correction part 10, with respect to the matrix on which the blank emphasis process is performed.

FIG. 10A shows a pattern printed on a recording medium in a case where the printer engine 102 prints the matrix of FIG. 9C showing the result of performing the smoothing process by the smoothing part 8. Further, FIG. 10B shows a pattern printed on the recording medium in a case where the printer engine 102 prints the matrix of FIG. 9F showing the result of performing the color correction by the correction part 10. For the sake of convenience, each square indicates a printing position of each pixel (dot), and each circle indicates a size and position of a dot to be actually printed.

In the above mentioned embodiment, for convenience of explanation, a process is performed using the matrix (window) of 4 pixels×5 pixels. However, the size of the matrix is not limited to 4 pixels×5 pixels. It is possible to use a matrix (window) of m pixels×n pixels (m and n are integers). In this case, m may be equal to n, or m may not be equal to n. Further, the number of the gradation levels is not limited to 16 as long as the number is a plural number.

In addition, the primary colors used by the printer in printing are not limited to Y, M, C and K. Further, the primary colors used in displaying on the display are, for example, red (R), green (G) and blue (B).

In the above-mentioned embodiment, the present invention is applied to the color printer. However, needless to say, it is possible to apply the present invention to a monochromatic printer, which prints multi-valued image data, in the same way.

The present invention is not limited to the specifically disclosed embodiments, and variations and modifications may be made without departing from the scope of the present invention.

The present application is based on Japanese priority application No. 2001-241200 filed Aug. 8, 2001, the entire contents of which are hereby incorporated by reference.

What is claimed is:

1. An image processing method that processes input image data represented by a plurality of gradation levels from a minimum to a maximum, comprising:
a first binarization step that extracts a matrix of m pixels×n pixels (m, n: integer) from said input image data, and performs a binarization process on each pixel in said matrix so that each of the pixels having the minimum gradation level is binarized into “0”, and each of the pixels having a level other than the minimum gradation level is binarized into “1”;
a blank emphasis step that performs a blank emphasis process on each pixel in a matrix binarized in said first binarization step; and
a correction step that performs a color correction process on each of the pixels in the matrix subjected to the blank emphasis process in said blank emphasis step.

2. The image processing method as claimed in claim 1, wherein the correction step performs a correction process on each of the pixels in the matrix subjected to the blank emphasis, said correction process being represented by: (data value after blank emphasis)×{(gradation level of input image data)/(the maximum gradation level)}.

3. The image processing method as claimed in claim 1, wherein the input image data are color image data, and the first binarization step, the blank emphasis step and the correction step are performed on each primary color of said color image data independently.

4. The image processing method as claimed in claim 1, further comprising:
a second binarization step that extracts a matrix of m pixels×n pixels from the input image data and performs a binarization process on each pixel in said matrix so that each of the pixels having the maximum gradation level is binarized into “1”, and each of the pixels having a level other than the maximum gradation level is binarized into “0”;
a smoothing step that performs a smoothing process on each pixel in a matrix binarized in said second binarization step; and
an output step that, according to a priority, selects and outputs either data obtained in the correction step or data obtained in said smoothing step.

5. The image processing method as claimed in claim 1, further comprising:
a second binarization step that extracts a matrix of m pixels×n pixels from the input image data and performs a binarization process on each pixel in said matrix so that each of the pixels having the maximum gradation level is binarized into “1”, and each of the pixels having a level other than the maximum gradation level is binarized into “0”;
a smoothing step that performs a smoothing process on each pixel in a matrix binarized in said second binarization step; and
a step that selects, according to a priority, whether to make the first binarization step, the blank emphasis step and the correction step valid, or to make only said second binarization step and said smoothing step valid.

6. An image output apparatus that processes and outputs input image data represented by a plurality of gradation levels from a minimum to a maximum, comprising:
a binarization part that extracts a matrix of m pixels×n pixels (m, n: integer) from said input image data, and performs a binarization process on each pixel in said matrix so that each of the pixels having the minimum gradation level is binarized into “0”, and each of the pixels having a level other than the minimum gradation level is binarized into “1”;
a blank emphasis part that performs a blank emphasis process on each pixel in a matrix binarized in said first binarization part; and
a correction part that performs a color correction process on each of the pixels in the matrix subjected to the blank emphasis process by said blank emphasis part.

7. The image output apparatus as claimed in claim 6, wherein the correction part performs a correction process on each of the pixels in the matrix subjected to the blank emphasis process, said correction process being represented by: (data value after blank emphasis)×{(gradation level of input image data)/(the maximum gradation level)}.

8. The image output apparatus as claimed in claim 6 or 7, wherein the input image data are color image data, and the first binarization part, the blank emphasis part and the correction part independently perform respective processes to each primary color of said color image data.

9. The image output apparatus as claimed in claim 6, further comprising:
a second binarization part that extracts a matrix of m pixels×n pixels from the input image data, and performs a binarization process on each pixel in said matrix so that each of the pixels having the maximum gradation level is binarized into “1”, and each of the pixels having a level other than the maximum gradation level is binarized into “0”;
a smoothing part that performs a smoothing process on each pixel in a matrix binarized in said second binarization part; and
an output part that selects and outputs, according to a priority, either data obtained by the correction part or data obtained by said smoothing part.

10. The image output apparatus as claimed in claim 6, further comprising:
a second binarization part that extracts a matrix of m pixels×n pixels from the input image data, and performs a binarization process on each pixel in said matrix so that each of the pixels having the maximum gradation level is binarized into “1”, and each of the pixels having a level other than the maximum gradation level is binarized into “0”;
a smoothing part that performs a smoothing process on each pixel in a matrix binarized in said second binarization part; and
a selecting means that selects, according to a priority, whether to make the first binarization part, the blank emphasis part and the correction part valid, or to make only said second binarization part and said smoothing part valid.

11. The image output apparatus as claimed in claim 9, further comprising a means that determines the priority.

12. The image output apparatus as claimed in claim 9, further comprising a means that prints or displays data selected and output by the selecting means.
